(19) United States
(12) Patent Application Publication
(10) Pub. No.: US 2013/0105648 A1
(43) Pub. Date: May 2, 2013

(54) MOUNTING DEVICE FOR EXPANSION CARD

(71) Applicants: TING-TING HE, Wuhan City (CN); ZHI-PING WU, Wuhan City (CN)

(72) Inventors: TING-TING HE, Wuhan City (CN); ZHI-PING WU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/565,779

(22) Filed: Aug. 2, 2012

(30) Foreign Application Priority Data
Oct. 27, 2011 (CN) 201110331580.9

(51) Int. Cl. H05K 7/00; F16M 13/02

(52) U.S. Cl. 248/221.11

(57) ABSTRACT

A mounting device for an expansion card includes a chassis, a retaining member, a bracket, and a securing member. The chassis includes a front plate. The front plate includes an expansion window and a supporting portion substantially perpendicular to the expansion window. The retaining member is rotatably mounted on the front plate about an axis extending through the supporting portion. The retaining member includes a retaining board. The retaining member retains a first end of the expansion card to the supporting portion. The bracket is mounted on the chassis. The securing member is fixed on the bracket. The securing member secures a second end of the expansion card to the chassis.

### BACKGROUND

1. Technical Field

The present disclosure relates to a mounting device for retaining expansion cards in a computer chassis.

2. Description of Related Art

A computer system usually includes expansion cards, such as PCI card, graphics cards, for example, for enhancing capabilities of the computer system. The expansion cards are often fastened in the computer system with screws at one side. However, installing screws to fix the expansion cards is very laborious and time-consuming, and only one side of the expansion card fastens making the expansion card unstable. Therefore, there is room for improvement within the art.

### BRIEF DESCRIPTION OF THE DRAWINGS

FIG. 1 is a partial exploded, schematic view of one embodiment of a mounting device for an expansion card.

FIG. 2 is similar to FIG. 1, but shown from another aspect.

FIG. 3 is an enlarged view of a retaining member of the mounting device of FIG. 1.

FIG. 4 is a partial assembled view of the mounting device of FIG. 1.

FIG. 5 is an assembled view of the mounting device of FIG. 1, but a bracket is in an open state.

FIG. 6 is an assembled view of the mounting device of FIG. 1.

FIG. 7 is an enlarged view of circled portion VI of FIG. 6.

FIG. 8 is a cross sectional view along a line VII-VII of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

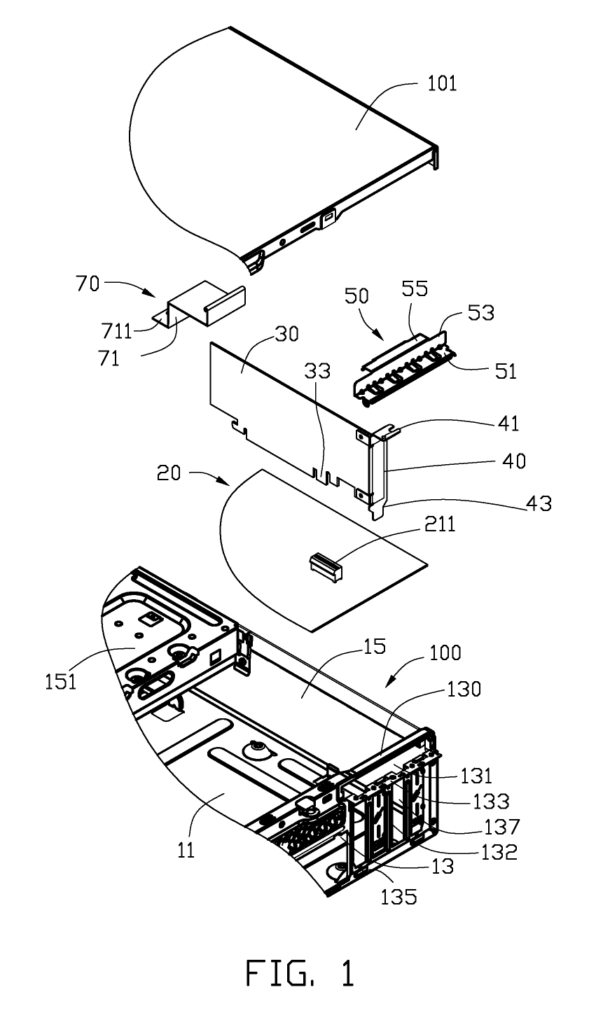

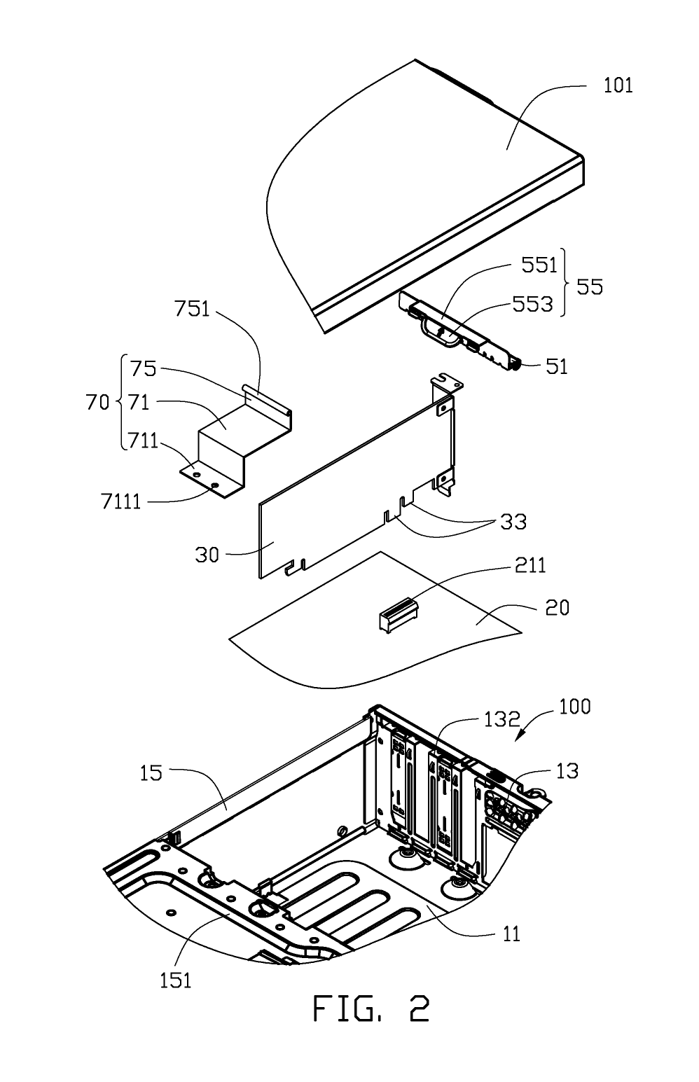

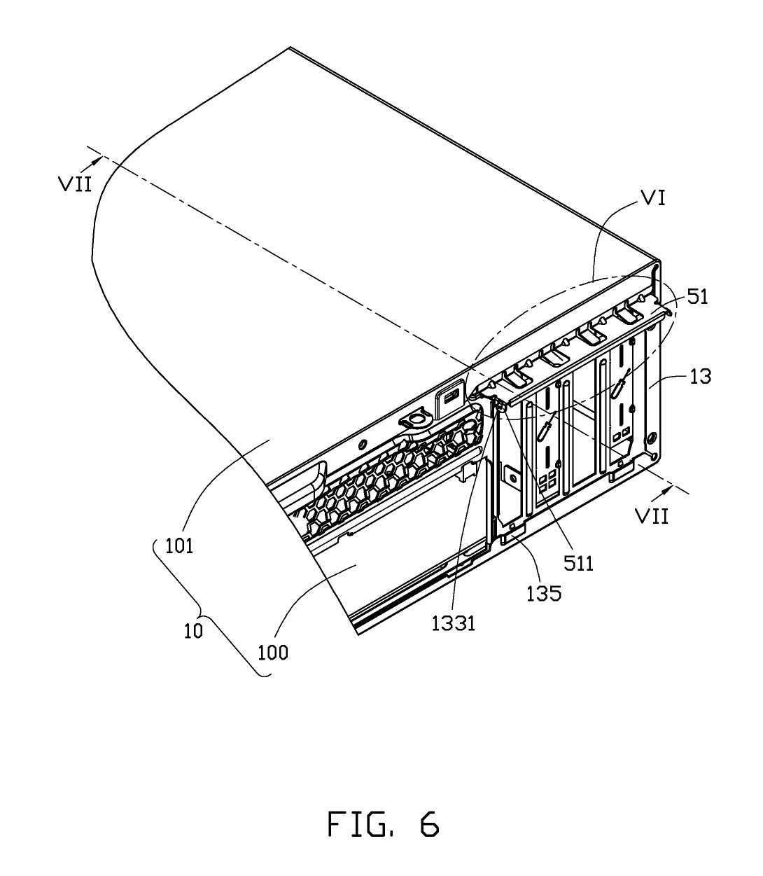

FIG. 1, FIG. 2 and FIG. 6, illustrate one embodiment of a mounting device 10. The mounting device 10 includes a chassis 100, a motherboard 20 located on the chassis 100, a retaining member 50, a securing member 70, and a top cover 101. The mounting device 10 can mount an expansion card 30 to the chassis 100.

The expansion card 30 includes a connector 33. A block piece 40 is mounted to the expansion card 30. The block piece 40 includes a positioning portion 41, an insert portion 43. The motherboard 20 includes a connector receiver 211 for receiving the connector 33 of the expansion card 30.

The chassis 100 includes a bottom wall 11, a sidewall 15 and a front plate 13. A bracket 151 is rotatably mounted on the chassis 100. The front plate 13 includes an expansion window 132, a supporting portion 133 perpendicular to the expansion window 132, and a top flange 130. An opening 131 is defined between the top flange and the expansion window 132. The expansion window 132 defines a plurality of expansion slots 137 for receiving the expansion card 30.

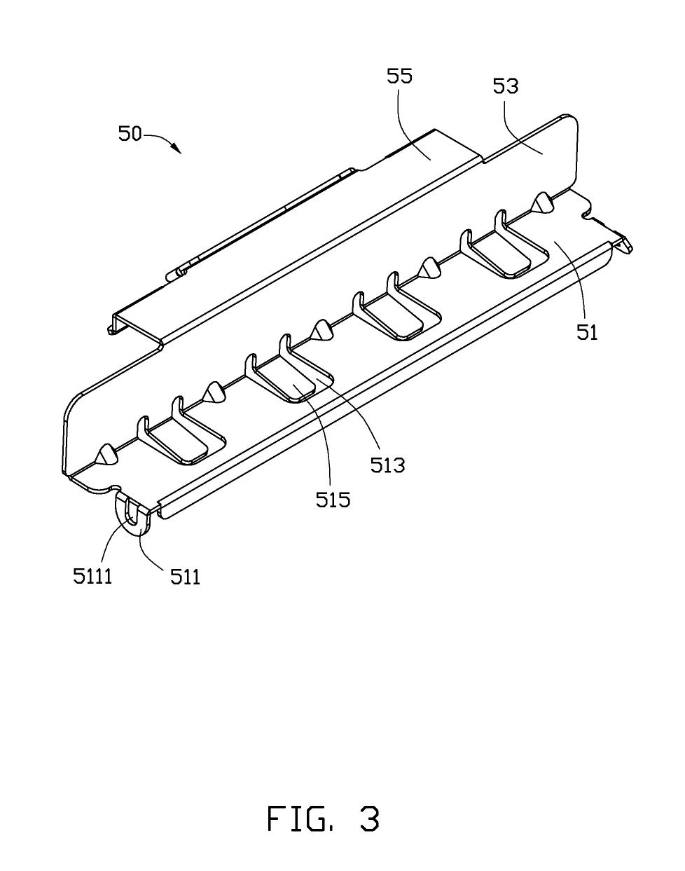

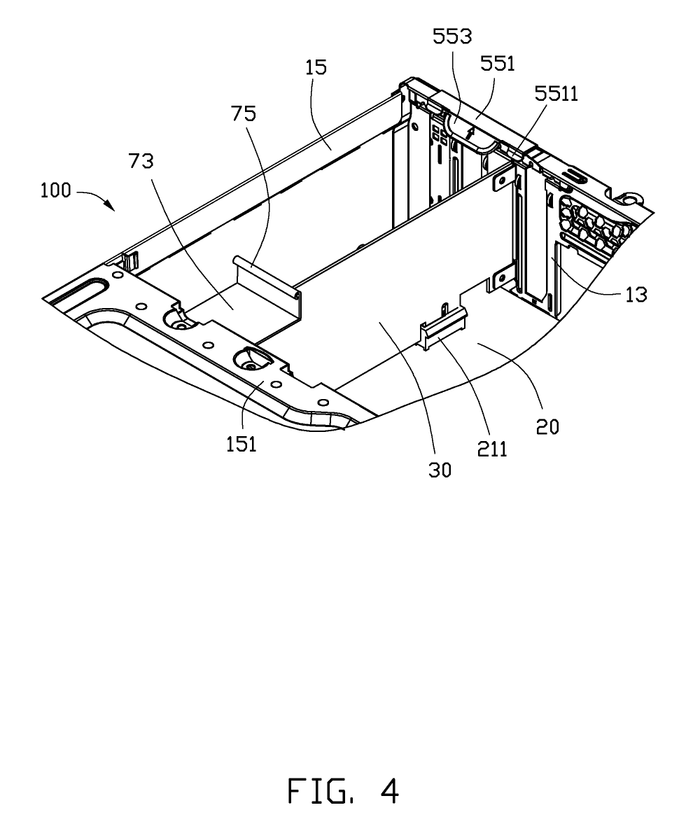

FIG. 3 and FIG. 4, illustrates the retaining member 50 of the embodiment. The retaining member 50 includes a pressing board 51, a connecting board 53, and an operating portion 55. The pressing board 51 includes a plurality of resilient feet 515. The plurality of resilient feet 515 are angled relative to the pressing board 51. A plurality of receiving openings 513 are defined in the pressing board 51 for receiving the plurality of resilient feet 515. A pair of rotating portions 511 extends down from opposite sides of the pressing board 51. Each of the pair of rotating portions 511 defines a rotating hole 5111. The operating portion 55 includes an expansion board 551, a tab 553 and two retaining clasps 5511.

The securing member 70 includes a fixing portion 711, a first securing board 71, a second securing board 73 and a pull portion 75. The fixing portion 711 defines two securing holes 7111. The first securing board 71 is substantially perpendicular to the second securing board 73. The pull portion 75 has a roller flange 751.

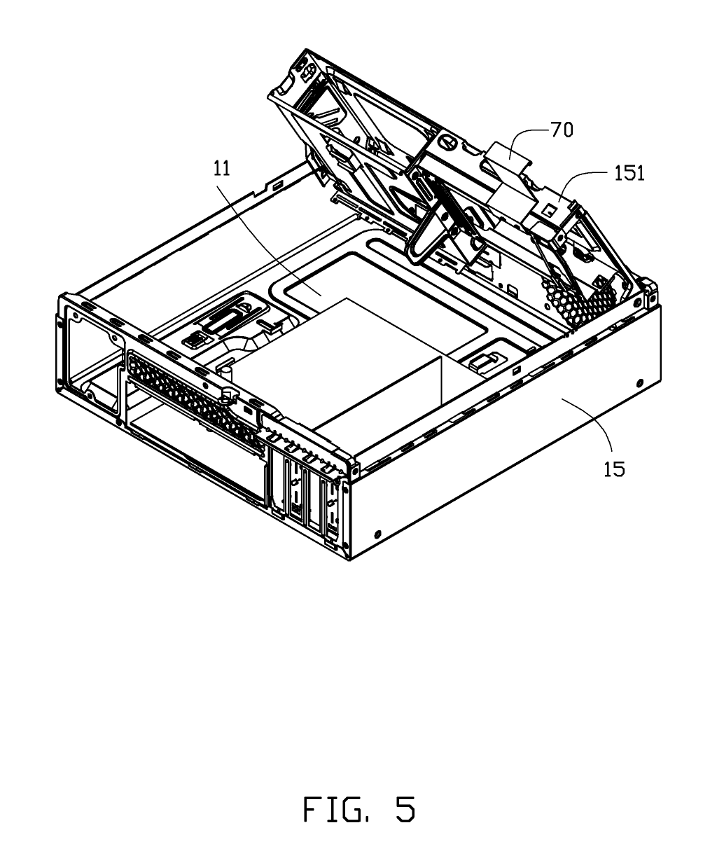

Referring to FIG. 5, in assembly, the securing member 70 is mounted to an outer end of the bracket 151. The bracket 151 can rotate relative to the chassis 100 with the securing member 70.

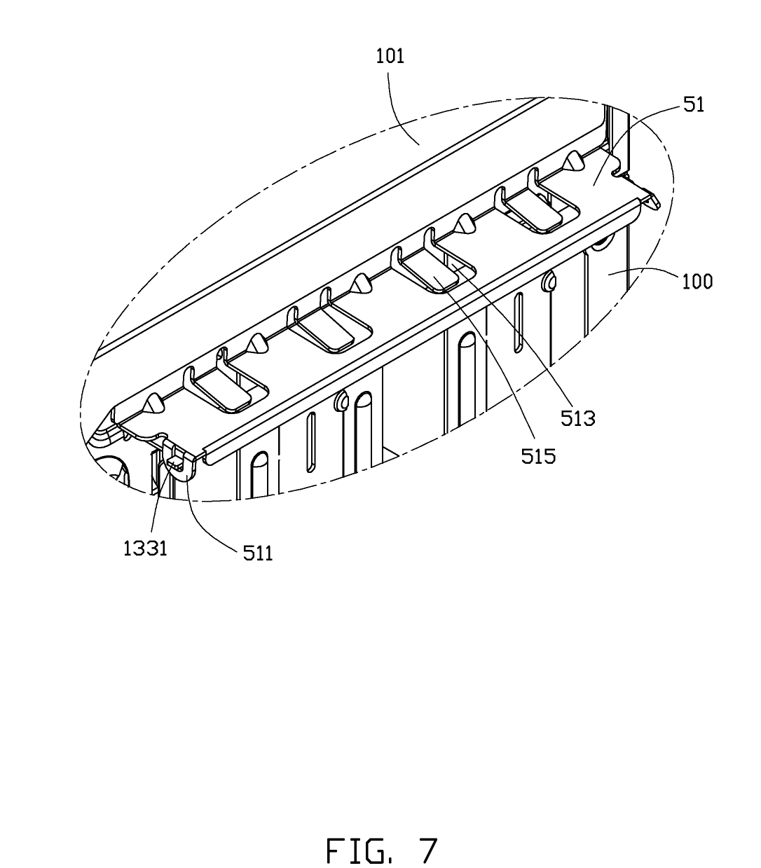

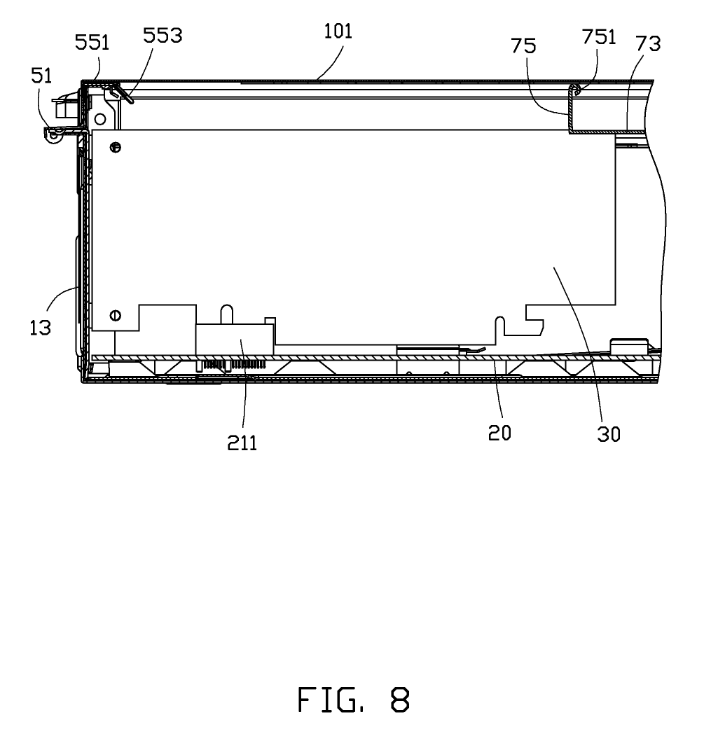

Referring to FIG. 6 to FIG. 8, the retaining member 50 is mounted to the front plate 13. The retaining member 50 is rotated about an axis 1331 which extends along an outer edge of the supporting portion 133.

When retaining the expansion card 30, the expansion card 30 is plugged to the motherboard 20. The block piece 40 is mounted to the expansion card 30. The block piece 40 extends through the opening 131 of the front plate 13. The block piece 40 shields one of the slots 137. The retaining member 50 can be rotated to a retaining state to retain a first side of the expansion card 30. In the retaining state, the plurality of feet 515 presses the positioning portion 41 of the retaining member 50. The operating portion 55 is located on a top surface of the top flange 130. The retaining clasps 5511 engages with the top flange 130. The securing member 70 is rotated to a secured state.

In the secured state, the securing member 70 secures a second side of the expansion card 30. The second side of the expansion card 30 is opposite to the first side of the expansion card 30. The first securing board 71 and the second securing board 73 cooperatively secure the second end of the expansion card 30. The top cover 101 covers on the chassis 100 to retain the bracket 151 and press the expansion board 551 to the top flange 130.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A mounting device for an expansion card comprising:
a chassis comprising a front plate, the front plate comprising an expansion window and a supporting portion substantially perpendicular to the expansion window, and a plurality of slots defined in the expansion window;
a retaining member rotatably mounted on the front plate about an axis extending through the supporting portion, the retaining member comprising a retaining board;
a bracket mounted on the chassis; and
a securing member fixed on the bracket, the securing member comprising a first securing board and a second securing board, the first securing board being substantially perpendicular to the second securing board,
wherein the securing member is located away from the front plate.

2. The mounting device of claim 1, wherein the axis is defined in an outer edge of the supporting portion.

3. The mounting device of claim 2, wherein the retaining member further comprises a connection board substantially perpendicular to the pressing board, and the connection board is located away from the axis.

4. The mounting device of claim 1, wherein the front plate further comprises a top flange, and the retaining member further comprises an operating portion mounted on the top flange.

5. The mounting device of claim 4 further comprising a top cover, wherein the top cover is adapted to retain the operation portion to the top flange.

6. The mounting device of claim 5, wherein the operation portion comprises an extension board and a tab biased from the extension board.

7. The mounting device of claim 1, wherein the retaining board comprises a plurality of resilient feet biasing toward the supporting portion.

8. The mounting device of claim 1, wherein the bracket is rotatable relative to the chassis, and the first securing board and the second securing board are perpendicular to the expansion card.

9. A mounting device for an expansion card comprising:
a chassis comprising a front plate, the front plate comprising an expansion window and a supporting portion substantially perpendicular to the expansion window, and a plurality of slots defined in the expansion window;
a retaining member rotatably mounted on the front plate about an axis extending through the supporting portion, the retaining member comprising a retaining board corresponding to the supporting portion; and
a top cover, the top cover adapted to retain the retaining member to the front plate,
wherein the axis is defined in an outer edge of the supporting portion.

10. The mounting device of claim 9 further comprising a bracket mounted on the chassis; and a securing member fixed on the bracket, wherein the securing member is located away from the retaining member.

11. The mounting device of claim 10, wherein the securing member comprises a first securing board and a second securing board, the first securing board being substantially perpendicular to the second securing board, and the first securing board and the second securing board securing the second end of the expansion card.

12. The mounting device of claim 9, wherein the retaining member further comprises a connection board substantially perpendicular to the pressing board, and the connection board is located away from the axis.

13. The mounting device of claim 9, wherein the front plate further comprises a top flange, and the retaining member further comprises an operating portion mounted on the top flange.

14. The mounting device of claim 13, wherein the operating portion comprises an extension board and a tab biased from the extension board, and the tab is located under the top cover.

15. The mounting device of claim 9, wherein the retaining board comprises a plurality of resilient feet biasing toward the supporting portion.

16. The mounting device of claim 9, wherein the bracket is rotatable relative to the chassis, and the first securing board and the second securing board are perpendicular to the expansion card.

17. A mounting device comprising:
a front plate comprising an expansion window and a supporting portion substantially perpendicular to the expansion window, and a plurality of slots defined in the expansion window;
a retaining member rotatably mounted, on the front plate, about an axis extending through the supporting portion, and the retaining member comprises a retaining board; and
a securing member comprising a first securing board and a second securing board, the first securing board is substantially perpendicular to the second securing board,
wherein the securing member is located away from the front plate, and the retaining member and the securing member are located on opposite sides of the front plate.
